(19) United States
(12) Patent Application Publication
(10) Pub. No.: US 2005/0006793 A1
(43) Pub. Date: Jan. 13, 2005

(54) Semiconductor device and method of manufacturing the same, circuit board, and electronic instrument

(75) Inventor: Jun Taniguchi, Nerima-ku (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/856,998

(22) Filed: Jun. 1, 2004

(30) Foreign Application Priority Data
Jun. 27, 2003 (JP) 2003-184574

(51) Int. Cl. H01L 23/34

(52) U.S. Cl. 257/787

(57) ABSTRACT

A semiconductor device includes a semiconductor element including an electrode; a substrate on which an interconnect pattern is formed; a protective film formed to cover the interconnect pattern in a second region other than a first region in which the semiconductor element is mounted; and an adhesive sheet which bonds the semiconductor element to the substrate. The protective film includes an end portion which is formed to become thinner toward the first region. The adhesive sheet is formed to extend from at least the first region of the substrate and to cover the end portion of the protective film.

Japanese Patent Application No. 2003-184574, filed on Jun. 27, 2003, is hereby incorporated by reference in its entirety.

### BACKGROUND OF THE INVENTION

The present invention relates to a semiconductor device and a method of manufacturing the same, a circuit board, and an electronic instrument.

In recent years, accompanied by reduction of the size of electronic instruments, a package for a semiconductor device suitable for high-density mounting has been demanded. To deal with this demand, a surface-mount package such as a ball grid array (BGA) or chip scale/size package (CSP) has been developed. In the surface-mount package, a substrate provided with an interconnect pattern to be connected with a semiconductor element may be used.

As a conventional surface-mount package, a semiconductor device in which the semiconductor element is secured to the interconnect pattern of the substrate using an adhesive sheet such as an anisotropic conductive film (ACF) or a non-conductive film (NCF) has been known (see Japanese Patent Application Laid-open No. 2001-21333, for example).

In a conventional semiconductor device, air may enter between a protective film on the substrate and the adhesive sheet when covering the interconnect pattern of the substrate with the adhesive sheet, whereby a void may be formed. Since the adhesive sheet tends to be removed during heating for curing the adhesive sheet or for reflowing due to expansion of the void, it is difficult to prevent occurrence of migration.

### BRIEF SUMMARY OF THE INVENTION

According to one aspect of the present invention, there is provided a semiconductor device comprising:
a semiconductor element including an electrode;
a substrate on which an interconnect pattern is formed;
a protective film formed to cover the interconnect pattern in a second region other than a first region of the substrate, the semiconductor element being mounted in the first region; and
an adhesive sheet which bonds the semiconductor element to the substrate,
wherein the protective film includes an end portion which is formed to become thinner toward the first region, and
wherein the adhesive sheet is formed to extend from at least the first region of the substrate and to cover the end portion of the protective film.

According to another aspect of the present invention, there is provided a method of manufacturing a semiconductor device, comprising:
forming an interconnect pattern on a substrate;
forming a protective film so as to cover the interconnect pattern in a second region other than a first region of the substrate, a semiconductor element being mounted in the first region; and
providing an adhesive sheet in a region including at least the first region and an end portion of the protective film, and bonding the semiconductor element to the substrate by the adhesive sheet,
wherein the end portion of the protective film is formed to become thinner toward the first region.

According to a further aspect of the present invention, there is provided a circuit board on which one of the above semiconductor devices is mounted.

According to still another aspect of the present invention, there is provided an electronic instrument comprising one of the above semiconductor devices.

### BRIEF DESCRIPTION OF THE SEVERAL VIEWS OF THE DRAWING

FIG. 1 is a cross-sectional view of a semiconductor device according to an embodiment of the present invention.

FIGS. 2A to 2D are views illustrating a method of manufacturing a semiconductor device according to an embodiment of the present invention.

FIG. 3 is a view showing a circuit board on which a semiconductor device according to an embodiment of the present invention is mounted.

FIG. 4 is a view showing an electronic instrument including a semiconductor device according to an embodiment of the present invention.

FIG. 5 is a view showing another electronic instrument including a semiconductor device according to an embodiment of the present invention.

FIG. 6 is a view showing a modification of a semiconductor device according to an embodiment of the present invention.

FIG. 7 is a view showing another modification of a semiconductor device according to an embodiment of the present invention.

### DETAILED DESCRIPTION OF THE EMBODIMENT

An objective of embodiments of the present invention is to provide a highly reliable semiconductor device having a structure in which a protective film is covered with an adhesive sheet, a method of manufacturing the same, a circuit board, and an electronic instrument.

(1) According to one embodiment of the present invention, there is provided a semiconductor device comprising:
a semiconductor element including an electrode;
a substrate on which an interconnect pattern is formed;
a protective film formed to cover the interconnect pattern in a second region other than a first region of the substrate, the semiconductor element being mounted in the first region; and
an adhesive sheet which bonds the semiconductor element to the substrate,
wherein the protective film includes an end portion which is formed to become thinner toward the first region, and
wherein the adhesive sheet is formed to extend from at least the first region of the substrate and to cover the end portion of the protective film.

According to the embodiment of the present invention, when the semiconductor element and the substrate are bonded by disposing the adhesive sheet between the semiconductor element and the substrate, a surface to which the adhesive sheet is attached can be formed by the first region of the substrate and the end portion which becomes thinner toward the first region. In other words, the adhesive sheet can be attached to a smooth surface with no large level difference. This configuration prevents air from entering between the adhesive sheet and the substrate, whereby a void is rarely formed.

(2) In the semiconductor device, the end portion may include an inclined surface.

The end portion which becomes thinner toward the first region in the direction of the thickness of the protective film may be in the shape of a projection insofar as the end portion includes the inclined surface. The end portion may be in the shape of a recess. This configuration enables the above-described effects and advantages to be achieved.

(3) In the semiconductor device, the end portion may further include a rising surface which rises from the interconnect pattern.

(4) In the semiconductor device, the end portion of the protective film may be formed in a stepped shape consisting of at least two steps in a thickness direction of the protective film.

(5) In the semiconductor device, an inclination angle of the inclined surface may be more than 0°, but less than 60°.

(6) In the semiconductor device, an inclination angle of the inclined surface may be more than 30°, but less than 45°.

(7) In the semiconductor device, the rising surface may be formed to have a height of more than 0 μm, but less than 10 μm from the interconnect pattern.

Since adhesive in the adhesive sheet has flexibility, the substrate and the protective film can be caused to adhere to each other even if a small level difference is formed.

(8) In the semiconductor device, the stepped shape may include at least two rising surfaces, and each of the rising surfaces may be formed to have a height of more than 0 μm, but less than 10 μm.

(9) In the semiconductor device, conductive particles may be dispersed in the adhesive sheet, and the interconnect pattern and the electrode may be electrically connected by the conductive particles.

(10) In the semiconductor device, the adhesive sheet may be an insulating sheet.

(11) In the semiconductor device, a treatment for providing affinity to a material for forming the protective film may be performed to at least the second region.

(12) According to another embodiment of the present invention, there is provided a method of manufacturing a semiconductor device, comprising:
forming an interconnect pattern on a substrate;
forming a protective film so as to cover the interconnect pattern in a second region other than a first region of the substrate, a semiconductor element being mounted in the first region; and
providing an adhesive sheet in a region including at least the first region and an end portion of the protective film, and bonding the semiconductor element to the substrate by the adhesive sheet,
wherein the end portion of the protective film is formed to become thinner toward the first region.

According to the embodiment of the present invention, when the semiconductor element and the substrate are bonded by disposing the adhesive sheet between the semiconductor element and the substrate, a surface to which the adhesive sheet is attached can be formed by the first region of the substrate and the end portion which becomes thinner toward the first region. In other words, the adhesive sheet can be attached to a smooth surface with no large level difference. This configuration prevents air from entering between the adhesive sheet and the substrate, whereby a void is rarely formed.

(13) In the method, the protective film may be formed to include an inclined surface at the end portion.

(14) In the method, the protective film may be formed to include a rising surface at the end portion, the rising surface rising from the interconnect pattern.

(15) In the method, a stepped shape may be formed at the end portion of the protective film, the stepped shape consisting of at least two steps in a thickness direction of the protective film.

(16) In the method, an inclination angle of the inclined surface may be more than 0°, but less than 60°.

(17) In the method, an inclination angle of the inclined surface may be more than 30°, but less than 45°.

(18) In the method, the rising surface may be formed to have a height of more than 0 μm, but less than 10 μm from the interconnect pattern.

(19) In the method, the stepped shape may include at least two rising surfaces, and each of the rising surfaces may be formed to have a height of more than 0 μm, but less than 10 μm.

(20) In the method, conductive particles may be dispersed in the adhesive sheet, and the interconnect pattern and the electrode may be electrically connected by the conductive particles.

(21) In the method, the adhesive sheet may be an insulating sheet.

(22) In the method, a treatment for providing affinity to a material for forming the protective film on the interconnect pattern may be performed to at least the second region before forming the protective film.

(23) According to a further embodiment of the present invention, there is provided a circuit board on which one of the above semiconductor devices is mounted.

(24) According to still another embodiment of the present invention, there is provided an electronic instrument comprising one of the above semiconductor devices.

The embodiments of the present invention are described below with reference to the drawings.

Semiconductor Device

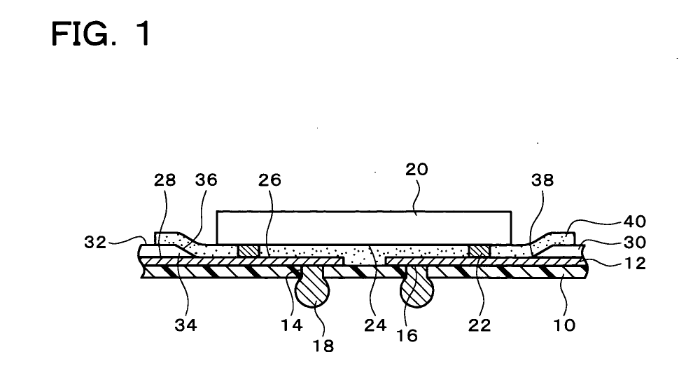

FIG. 1 is a cross-sectional view of a semiconductor device according to an embodiment of the present invention. An embodiment is described with reference to FIG. 1.

The semiconductor device according to the embodiment of the present invention includes a substrate 10. An interconnect pattern 12 is formed on at least one side of the substrate 10. The substrate 10 may be a substrate formed of an organic material such as a flexible substrate, a substrate formed of an inorganic material such as a metal substrate, or a substrate formed of a combination of these materials. A tape career may be used as the flexible substrate. A through-hole 14 is formed in the substrate 10. The interconnect pattern 12 is formed across the through-hole 14. A land 16 for forming an external electrode is formed on the through-hole 14 as a part of the interconnect pattern 12.

A protective film 30 is formed on the substrate 10. The protective film 30 covers the interconnect pattern 12 and protects the interconnect pattern 12 from moisture or the like. A solder resist is used as the protective film 30, for example.

The protective film 30 is formed to cover the interconnect pattern 12 in a second region 28 of the substrate 10 other than a first region 26 in which a semiconductor element 20 is mounted. The interconnect pattern 12 may include a connection land (not shown) to which an electrode 22 of the semiconductor element 20 is connected in the first region 26. The first region 26 is generally formed to have an area greater than the area of a surface 24 of the semiconductor element 20 having the electrode 22 formed thereon.

The protective film 30 includes a first surface 32 formed by a flat surface and an end portion 34 in the second region 28 of the substrate 10. The end portion 34 of the protective film 30 is formed so that the tip of the end portion 34 becomes thinner from the thickness of the area having the flat first surface 32 (about 20 μm, for example) toward the first region 26 in which the semiconductor element 20 is mounted.

The end portion 34 of the protective film 30 may be inclined as shown in FIG. 1. The surface of the end portion 34 may be an inclined surface 36 or a part of the end portion 34 may be inclined insofar as the tip of the end portion 34 is thinly formed. The inclined surface 36 may be in the shape of a projection or a recess. The inclined surface 36 may be connected with the flat first surface 32 or the surface of the first region 26 of the substrate through a curved surface.

The semiconductor device according to the embodiment of the present invention includes an adhesive sheet 40. The adhesive sheet 40 is placed between the semiconductor element 20 and the interconnect pattern 12, and secures the semiconductor element 20 to the substrate 10. The adhesive sheet 40 may be an anisotropic conductive film (ACF; also called an anisotropic conductive sheet), a non-conductive film (NCF), or the like.

The anisotropic conductive film may be a film in which conductive particles (conductive fillers) are dispersed in an adhesive (binder). A dispersant may be added. If the conductive particles are dispersed in the anisotropic conductive film, the interconnect pattern 12 and the electrode 22 can be electrically connected by the conductive particles. In the case of using an adhesive sheet (NCF, for example) which does not contain conductive particles, the interconnect pattern 12 and the electrode 22 are electrically connected by applying pressure.

As the adhesive in the adhesive sheet 40, a thermosetting adhesive represented by an epoxy adhesive or a photocurable adhesive represented by an epoxy or acrylate adhesive may be used. An electron-beam curing adhesive or a thermoplastic (thermobonding) adhesive may be used.

The adhesive sheet 40 may be formed in the shape of a sheet in advance. The adhesive sheet 40 is attached to extend from the first region 26 of the substrate 10 onto the end portion 34 of the protective film 30. The adhesive sheet 40 may cover the entire end portion 34 of the protective film 30, or may cover only a part of the end portion 34. It suffices that the adhesive sheet 40 be attached to extend from the first region 26 of the substrate 10 across the boundary between the first region 26 and the end portion 34 of the protective film 30. The adhesive sheet 40 may be provided on the semiconductor element 20, and then attached to the substrate 10.

Air rarely enters between the surface 38 and the adhesive sheet 40 by attaching the adhesive sheet 40 to the gently sloped surface 38 (surface without a large level difference) formed by the approximately flat first region 26 and the inclined surface 36. Specifically, since a large level difference is not formed, an air gap is rarely formed. The inclination angle of the inclined surface 36 is preferably more than 0°, but less than 60°. The inclination angle of the inclined surface 36 is still more preferably more than 30°, but less than 45°.

The semiconductor device according to the embodiment of the present invention includes the semiconductor element 20. The semiconductor element 20 is provided on the adhesive sheet 40. The semiconductor element 20 is provided so that the surface 24 having the electrode 22 faces the adhesive sheet 40. The semiconductor element 20 may be disposed so that the electrode 22 is located on the electrode connection land (not shown) of the interconnect pattern 12. The electrode 22 may be formed by an Al pad of the semiconductor element 20 and a bump such as a gold or solder bump provided on the Al pad. A bump such as a gold or solder bump may be provided on the interconnect pattern 12, or a bump may be formed by etching the interconnect pattern 12.

As shown in FIG. 1, a solder ball 18 may be provided on the substrate 10 so that the solder ball 18 projects from the through-hole 14, for example. The solder ball 18 becomes an external electrode.

In a semiconductor device 1 thus obtained, the adhesive sheet 40 is present between the semiconductor element 20 and the substrate 10, whereby the semiconductor element 20 is bonded to the substrate 10. The surface to which the adhesive sheet 40 is attached is formed by the first region 26 of the substrate 10 and the end portion 34 which becomes thinner toward the first region 26 (having an inclined surface). Specifically, the adhesive sheet 40 is attached to the smooth surface 38 having no large level difference. This configuration prevents air from entering between the adhesive sheet 40 and the substrate 10, whereby a void is rarely formed. Therefore, even if the semiconductor device is heated for curing the adhesive sheet 40 or for reflowing, occurrence of cracks in the adhesive sheet 40 due to expansion of a void or migration of the interconnect pattern 12 due to moisture which enters cracks can be prevented, since a void is not formed. Moreover, since the bonding area is increased, the bonding strength between the semiconductor element 20 and the substrate 10 can be secured.

According to the embodiment of the present invention, a highly reliable semiconductor device having a structure in which the protective film 30 is covered with the adhesive sheet 40 can be provided.

Method of Manufacturing Semiconductor Device

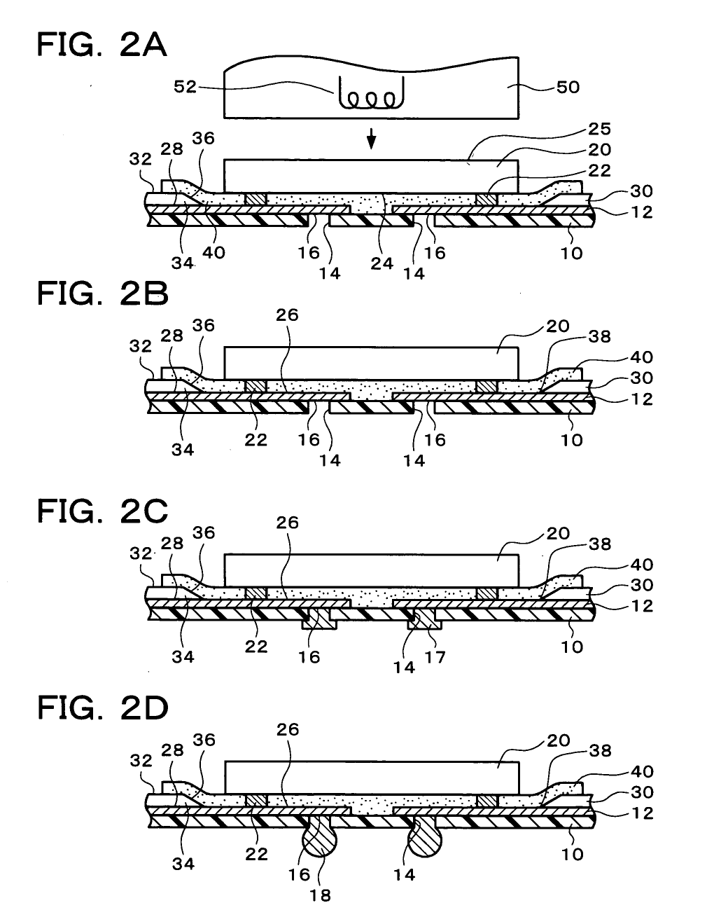

FIGS. 2A to 2D are views illustrating a method of manufacturing the semiconductor device according to the embodiment of the present invention.

(1) In the present embodiment, the substrate 10 with the interconnect pattern 12 formed on at least one side may be used, as shown in FIG. 2A (details are described above).

(2) The protective film 30 is formed on the substrate 10. A solder resist may be used as the protective film 30. The protective film 30 is formed to cover the interconnect pattern 12 in the second region 28 by a printing method using resin ink (screen printing method, for example). The first region 26 may be formed to have an area greater than the area of the surface 24 of the semiconductor element 20 having the electrode 22 formed thereon.

The protective film 30 is formed to include the flat first surface 32 and the end portion 34. The end portion 34 is formed to become thinner toward the first region 26 in which the semiconductor element 20 is mounted.

The second region 28 in which at least the protective film 30 is formed may be provided with a treatment for providing affinity to the material for forming the protective film 30. Wettability of the material for forming the protective film 30 with the substrate 10 is improved by providing the affinity treatment to the region in which the protective film 30 is formed, whereby the gently inclined surface 36 can be formed on the end portion 34 of the protective film 30.

The screen printing using resin ink may be performed two or more times. It is preferable to change the position of a mask for screen printing to a small extent in each screen printing. The protective film 30 may be formed by using a conventional screen printing method, and a surface pressing step and a chamfering step of the end portion 34 may be performed by machining.

The end portion 34 of the protective film 30 is formed to be inclined in this manner, as shown in FIG. 2A. The entire end portion 34 may be the inclined surface 36 or a part of the end portion 34 may be inclined insofar as the tip of the end portion 34 is thinly formed. The inclined surface 36 may be in the shape of a projection or a recess. The inclined surface 36 may be connected with the flat first surface 32 or the first region 26 of the substrate through a curved surface.

(3) The adhesive sheet 40 is attached to the substrate 10 on which the protective film 30 is formed. In the present embodiment, the adhesive sheet 40 is attached to extend from the first region 26 to the end portion 34 of the protective film 30. The adhesive sheet 40 may cover the entire end portion 34 of the protective film 30, or may cover only a part (tip) of the end portion 34. It suffices that the adhesive sheet 40 be attached to extend from the first region 26 across the boundary between the first region 26 and the end portion 34 of the protective film 30. The adhesive sheet 40 may be provided on the semiconductor element 20, and then attached to the substrate 10. This enables the adhesive sheet 40 to be bonded to the gently sloped surface 38, whereby air can be prevented from entering between the adhesive sheet 40 and the substrate 10.

(4) The semiconductor element 20 is placed on the adhesive sheet 40. The semiconductor element 20 is placed so that the surface 24 of the semiconductor element 20 having the electrode 22 faces the adhesive sheet 40. The semiconductor element 20 may be disposed so that the electrode 22 is located on the electrode connection land (not shown) of the interconnect pattern 12. The adhesive sheet 40 may be provided on the substrate 10 before mounting the semiconductor element 20, or may be provided on the surface 24 of the semiconductor element 20 having the electrode 22.

(5) The semiconductor element 20 is pressed against the substrate 10 by pressing a jig 50 against a surface 25 of the semiconductor element 20 opposite to the surface 24 having the electrode 22. Or, pressure is applied to the semiconductor element 20 and the substrate 10. This step causes the electrode 22 of the semiconductor element 20 and the interconnect pattern 12 to be electrically connected by the conductive particles in the adhesive sheet 40. The semiconductor element 20 is heated using a heater 52 included in the jig 50. A thermosetting adhesive represented by an epoxy adhesive is used as the adhesive in the adhesive sheet 40. Therefore, the adhesive sheet 40 is cured in the contact region with the semiconductor element 20, whereby the semiconductor element 20 can be bonded and secured to the substrate 10 (see FIG. 2B).

In the case of applying heat to the adhesive sheet 40 in the area larger than the area of the semiconductor element 20, the jig 50 may have a surface area greater than the surface area of the semiconductor element 20. This causes heat to be easily applied to the peripheral section of the semiconductor element 20, whereby the adhesive can be cured and the semiconductor element 20 can be secured more reliably.

(6) The external electrode is formed. As shown in FIG. 2C, a solder 17 may be provided inside of and near the through-hole 14 in the substrate 10. The solder 17 may be provided by a printing method using cream solder, for example. A solder ball formed in advance may be placed at the above position. The solder 17 is heated in a reflow step to form the solder ball 18 as shown in FIG. 2D. The solder ball 18 becomes the external electrode. In the reflow step, not only the solder 17, but also the adhesive sheet 40 is heated. An uncured region of the adhesive sheet 40 is cured by this heating. According to the embodiment of the present invention, a highly reliable semiconductor device having a structure in which the protective film 30 is covered with the adhesive sheet 40 can be provided.

Circuit Board and Electronic Instrument

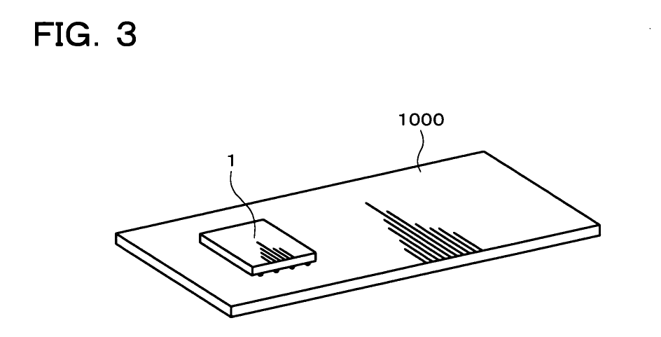

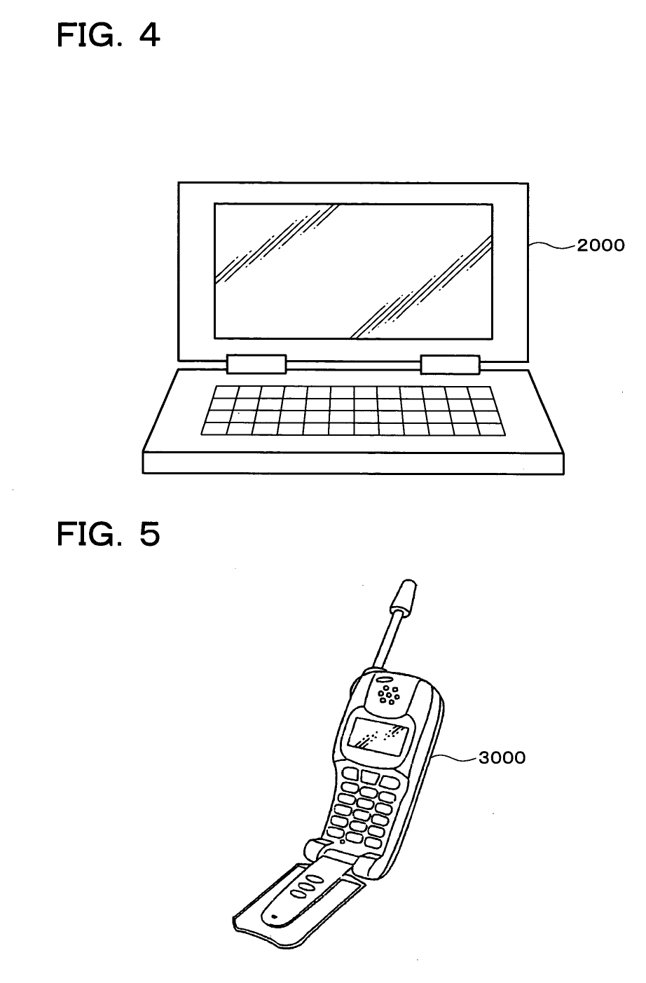

FIG. 3 shows a circuit board 1000 on which the semiconductor device 1 according to the embodiment of the present invention is mounted. FIG. 4 shows a notebook-type personal computer 2000 as an electronic instrument including the semiconductor device 1. FIG. 5 shows a portable telephone 3000.

Modification

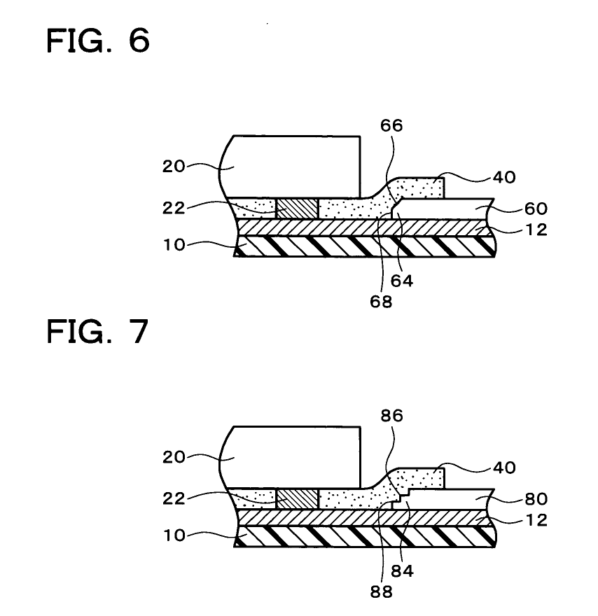

FIGS. 6 and 7 are cross-sectional views of a semiconductor device according to a modification of the embodiment of the present invention. In the example shown in FIG. 6, an end portion 64 of a protective film 60 includes an inclined surface 66 and a rising surface 68 which rises from the substrate 10. The inclined surface 66 is formed on the upper part of the end portion 64. The rising surface 68 is formed at a height of more than 0 μm, but less than 10 μm from the interconnect pattern 12 of the substrate.

The shape shown in FIG. 6 may be formed when forming the protective film 60 using a screen printing method by adjusting the amount of resin ink for the end portion 64 by changing a mesh of a mask for screen printing corresponding to the end portion 64 of the protective film 60 for each area. The shape shown in FIG. 6 may be formed by performing resin screen printing two or more times. The protective film 60 may be formed by using a conventional screen printing method, and the inclined surface 66 may be formed by performing a surface pressing step and a chamfering step of the end portion 64 by machining.

The adhesive sheet 40 is then attached in the same manner as in the above-described semiconductor device 1. Since the adhesive in the adhesive sheet 40 has flexibility, even if a level difference with a height of 0-10 μm exists, the adhesive sheet 40 enters the level difference and can be attached in an adhering state.

In the example shown in FIG. 7, an end portion 84 of a protective film 80 is formed in a stepped shape 86 consisting of at least two steps in the direction of the thickness of the protective film 80. The stepped shape 86 includes at least two rising surfaces 88, and is formed so that each of the rising surfaces 88 has a height of more than 0 μm, but less than 10 μm.

The stepped shape 86 shown in FIG. 7 may be formed when forming the protective film 80 using a screen printing method by performing screen printing using resin ink two or more times while changing the position of a mask for printing in each printing.

The adhesive sheet 40 is then attached in the same manner as in the above-described semiconductor device 1. Since the adhesive in the adhesive sheet 40 has flexibility, even if the rising surface 88 of the stepped shape 86 has a level difference with a height of 0-10 μm, the adhesive sheet 40 enters the level difference and can be attached in an adhering state.

According to this modification, a highly reliable semiconductor device having a structure in which the protective film 30 is covered with the adhesive sheet 40 can be provided. The description of the above-described embodiment can be applied to this modification.

The present invention is not limited to the above-described embodiments. Various modifications and variations can be made. For example, the present invention includes configurations substantially the same as the configurations described in the embodiments (in function, in method and effect, or in objective and effect). The present invention also includes a configuration in which an unsubstantial portion in the above-described embodiments is replaced. The present invention also includes a configuration having the same effects as the configurations described in the embodiments, or a configuration capable of achieving the same objective. Further, the present invention includes a configuration in which a known technique is added to the configurations described in the embodiments.

1. A semiconductor device comprising:
a semiconductor element including an electrode;
a substrate on which an interconnect pattern is formed;
a protective film formed to cover the interconnect pattern in a second region other than a first region of the substrate, the semiconductor element being mounted in the first region; and
an adhesive sheet which bonds the semiconductor element to the substrate,
wherein the protective film includes an end portion which is formed to become thinner toward the first region, and
wherein the adhesive sheet is formed to extend from at least the first region of the substrate and to cover the end portion of the protective film.

2. The semiconductor device as defined in claim 1,
wherein the end portion includes an inclined surface.

3. The semiconductor device as defined in claim 2,
wherein the end portion further includes a rising surface which rises from the interconnect pattern.

4. The semiconductor device as defined in claim 1,
wherein the end portion of the protective film is formed in a stepped shape consisting of at least two steps in a thickness direction of the protective film.

5. The semiconductor device as defined in claim 2,
wherein an inclination angle of the inclined surface is more than 0°, but less than 60°.

6. The semiconductor device as defined in claim 2,
wherein an inclination angle of the inclined surface is more than 30°, but less than 45°.

7. The semiconductor device as defined in claim 3,
wherein the rising surface is formed to have a height of more than 0 μm, but less than 10 μm from the interconnect pattern.

8. The semiconductor device as defined in claim 4,
wherein the stepped shape includes at least two rising surfaces, and each of the rising surfaces is formed to have a height of more than 0 μm, but less than 10 μm.

9. The semiconductor device as defined in claim 1,
wherein conductive particles are dispersed in the adhesive sheet, and the interconnect pattern and the electrode are electrically connected by the conductive particles.

10. The semiconductor device as defined in claim 1,
wherein the adhesive sheet is an insulating sheet.

11. The semiconductor device as defined in claim 1,
wherein a treatment for providing affinity to a material for forming the protective film is performed to at least the second region.

12. A method of manufacturing a semiconductor device, comprising:
forming an interconnect pattern on a substrate;
forming a protective film so as to cover the interconnect pattern in a second region other than a first region of the substrate, a semiconductor element being mounted in the first region; and
providing an adhesive sheet in a region including at least the first region and an end portion of the protective film, and bonding the semiconductor element to the substrate by the adhesive sheet,
wherein the end portion of the protective film is formed to become thinner toward the first region.

13. The method as defined in claim 12,
wherein the protective film is formed to include an inclined surface at the end portion.

14. The method as defined in claim 12,
wherein the protective film is formed to include a rising surface at the end portion, the rising surface rising from the interconnect pattern.

15. The method as defined in claim 12,
wherein a stepped shape is formed at the end portion of the protective film, the stepped shape consisting of at least two steps in a thickness direction of the protective film.

16. The method as defined in claim 13,
wherein an inclination angle of the inclined surface is more than 0°, but less than 60°.

17. The method as defined in claim 13,
wherein an inclination angle of the inclined surface is more than 30°, but less than 45°.

18. The method as defined in claim 14,
wherein the rising surface is formed to have a height of more than 0 μm, but less than 10 μm from the interconnect pattern.

19. The method as defined in claim 15, wherein the stepped shape includes at least two rising surfaces, and each of the rising surfaces is formed to have a height of more than 0 μm, but less than 10 μm.

20. The method as defined in claim 12,
wherein conductive particles are dispersed in the adhesive sheet, and the interconnect pattern and the electrode are electrically connected by the conductive particles.

21. The method as defined in claim 12,
wherein the adhesive sheet is an insulating sheet.

22. The method as defined in claim 12,
wherein a treatment for providing affinity to a material for forming the protective film on the interconnect pattern is performed to at least the second region before forming the protective film.

23. A circuit board on which the semiconductor device as defined in claim 1 is mounted.

24. An electronic instrument comprising the semiconductor device as defined in claim 1.
